(19) United States
(12) Patent Application Publication
(10) Pub. No.: US 2010/0124720 A1
(43) Pub. Date: May 20, 2010

(54) MATERIAL FOR PROTECTIVE FILM FORMATION, AND METHOD FOR PHOTORESIST PATTERN FORMATION USING THE SAME

(75) Inventors: Keita Ishiduka, Kanagawa (JP); Kotaro Endo, Kanagawa (JP); Masaaki Yoshida, Kanagawa (JP)

Correspondence Address: HOFFMANN & BARON, LLP, 6900 JERICHO TURNPIKE, SYOSSET, NY, 11791, US

(73) Assignee: TOKYO OHKA KOGYO CO., LTD., Kanagawa (JP)

(21) Appl. No.: 11/995,291

(22) PCT Filed: Jul. 5, 2006
(86) PCT No.: PCT/JP2006/313425

§ 371 Date: Jan. 10, 2008

(30) Foreign Application Priority Data
Jul. 12, 2005 (JP) 2005-203150

(51) Int. Cl. G03F 7/20; G03F 7/004

(52) U.S. Cl. 430/271.1; 430/325

(57) ABSTRACT

This invention provides a material for protective film formation, comprising at least an alkali soluble polymer comprising at least one of constitutional units represented by general formulae (I) and (II) and an alcoholic solvent. The material for protective film formation can simultaneously prevent a deterioration in a resist film during liquid immersion exposure and a deterioration in a liquid for liquid immersion exposure used and, at the same time, can form a resist pattern with a good shape without the need to increase the number of treatment steps.

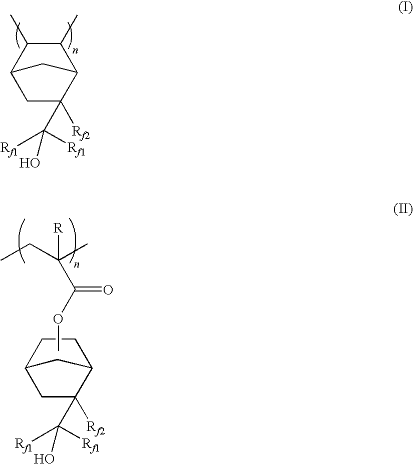

### TECHNICAL FIELD

The present invention relates to a material suitable for forming a protective film to a resist film, and a method for forming a photoresist pattern using the same. Particularly, the present invention relates to a material for forming a protective film suitably used in a liquid lithography process, in which the resolution of a resist pattern is improved by exposing a resist film in the state that a liquid having a predetermined thickness and refractive index larger than that of air and smaller than that of the resist film intervenes on at least the resist film on a route of lithographic exposure light reaching thereto, and a method for forming a photoresist pattern using the same.

### BACKGROUND ART

Conventionally, lithography process has been commonly used in fabricating fine structures in various kinds of electronic devices such as semiconductor devices and liquid crystal devices. However, along with the miniaturization of device structures, there is a need for micro-fabrication of resist patterns in a lithography process.

In the advanced field, for example, a lithography process now allows the formation of a fine resist pattern having a line width of about 90 nm. However, finer pattern formation will be required in future.

For attaining the formation of such a fine pattern having a line width of less than 90 nm, a first point is to develop an aligner and a resist corresponding thereto. Common factors to consider for developing the aligner include shortening the wavelengths of optical sources such as F₂ excimer laser, EUV (extreme UV light), electron beam, X-ray, and soft X-ray, and increasing the numerical aperture (NA) of lens.

On the other hand, shortening the wavelengths of the light sources requires a new and expensive aligner. In addition, there is an arisen problem that a focal depth width is reduced even if the resolving ability is improved because a trade-off lies between the resolving ability and the focal depth width when the NA is increased.

Recently, as a lithography technology for enabling solve such problems, a method known as a liquid immersion lithography process has been disclosed (e.g., Non-Patent Documents 1, 2, and 3). In this process, a liquid refractive index medium such as purified water or a fluorine-based inert liquid (liquid for liquid immersion lithography) is placed on the resist film in a predetermined thickness between a lens and the resist film. In this process, by filling a liquid having a higher refractive index (n) (e.g. purified water) in place of conventional inert gas such as air or nitrogen in the space of the path of exposure light, high resolution is attained without decreasing focal depth width in a similar way to that in which a light source of short wavelength or a high NA lens is used even if an optical source having the same exposure wavelength is employed.

This liquid immersion lithography has remarkably attracted attention because the formation of resist pattern exhibiting higher resolution as well as superior focal depth can be achieved in low cost by using a lens implemented in an existing device.

However, in such a liquid immersion lithography process, since a liquid for liquid immersion lithography such as purified water and a fluorine-based inert liquid intervenes on the upper layer of the resist film. Accordingly, it is natural that there is a concern such as the deterioration of resist film caused by the liquid for liquid immersion lithography during the liquid immersion lithography, and the fluctuation of the refractive index accompanied by the deterioration of the liquid itself due to eluted components from the resist film.

Although the materials used in a conventional lithography process may be utilized without any adjustment in such a liquid immersion lithography process, it has been proposed to use a material different from those of the conventional lithography process in a different exposure environment in which the liquid for liquid immersion lithography intervenes between a lens and a resist film.

Under these circumstances, a material for forming a protective film using a fluorine-containing resin have been proposed for simultaneously preventing the above-mentioned deterioration of the resist film caused by the liquid for liquid immersion lithography during the liquid immersion lithography and the fluctuation of the refractive index accompanied by the deterioration of the liquid itself (see Patent Document 1, for example). However, when such a material for forming a protective film is used, problems on the investment efficiency that a special cleaning solution and an applying device are required and the number of processes for removing the protective film is increased are arisen even though the aforementioned purpose is accomplished.

Furthermore, recently, a process using an alkali-soluble polymer as the protective film on the resist upper layer has attracted attention. However, there have been needs for characteristics enabling to suppress the deterioration of the resist film caused by the liquid for liquid immersion lithography during the liquid immersion lithography and the fluctuation of the refractive index accompanied by the deterioration of the liquid itself as much as possible.

Non Patent Document 1: Journal of Vacuum Science & Technology B (J. Vac. Sci. Technol. B) (Issued country: U.S.A.), Vol. 17, No. 6, pages 3306-3309, 1999.

Non Patent Document 2: journal of Vacuum Science & Technology B (J. Vac. Sci. Technol. B) (Issued country: U.S.A.), Vol. 19, No. 6, pages 2353-2356, 2001.

Non Patent Document 3: Proceedings of SPIE (Issued country: U.S.A.), Vol. 4691, pages 459-465, 2002.

Patent Document 1: International Publication No. WO 2004/074,937

### DISCLOSURE OF THE INVENTION

### Problems Solved by the Invention

The present invention was achieved in view of the above-mentioned problems of conventional art. Specifically, the objective of this invention is to enable to prevent the deterioration of the resist film and the immersion liquid itself during the liquid immersion lithography simultaneously and form a resist pattern with high-resolution capacity by using liquid immersion lithography by forming a specific protective film on the surface of the conventional resist film.

### Means for Solving the Problems

To solve the above-mentioned problems, a material for forming a protective film according to the present invention is a material for forming a protective film laminated on a photoresist film on a substrate, wherein the material being prepared by dissolving an alkali-soluble polymer having least any one of constitutional units represented by the following general formulas (I) and (II) in an alcoholic solvent,

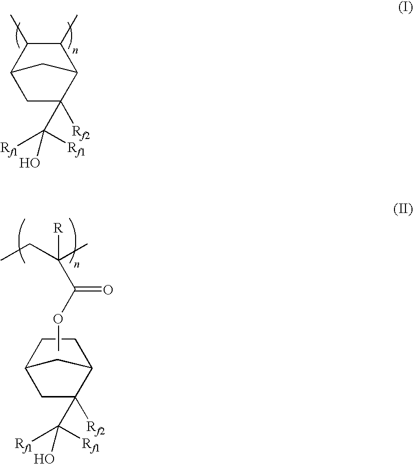

wherein, R_{f1} represents a liner, branched, or cyclic alkyl group having 1 to 5 carbon atoms, provided that some or hydrogen atoms of the alkyl group may be substituted with fluorine atoms; R_{f2} represents a hydrogen atom, a fluorine atom, or a liner, branched, or cyclic alkyl group having 1 to 5 carbon atoms, provided that some or of hydrogen atoms of the alkyl group may be substituted with fluorine atoms; at least any one of R_{f1} and R_{f2} has a fluorine substituent; R represents a hydrogen atom or a methyl group; and is an integer of riot less than 1, representing the number of repeating units.

Furthermore, a method for forming a resist pattern according to the present invention is a method for forming a photoresist pattern by using a liquid immersion lithography process, the method comprises a photoresist-forming step of forming a photoresist film on a substrate; a protective-film forming step of forming a protective film on the photoresist film by using the material for forming a photoresist protective film; an exposing step of selectively exposing the Photoresist film through a liquid for liquid immersion lithography and the protective film after the liquid for the liquid immersion lithography is placed at least on the protective film of the substrate; and a developing step of developing the protective film and the photoresist film by using an alkaline developing solution after a heat treatment is conducted to the photoresist film if necessary, thereby removing the protective film and obtaining a photoresist pattern at the same time.

### EFFECTS OF THE INVENTION

By using the material for forming a protective film according to the present invention, the protective film can be directly formed on the resist film and does not inhibit the pattern exposure. In addition, the material for forming a protective film of the present invention is water-insoluble and therefore makes it possible to actually use “water (purified water or deionized water) which is a most likely candidate for the liquid for liquid immersion used in liquid immersion lithography satisfying the optical requirements of liquid immersion lithography, being easy to handle, and being free from environmental pollution” as a liquid for immersion lithography. In other words, even when water, which is easy to handle, has an excellent optical properties such as a refractive index and is free from environmental pollution, is used as an immersion liquid for liquid immersion lithography, the material of the present invention sufficiently protects resist films of various compositions during the liquid immersion lithography process so that the resist patterns having excellent properties can be obtained. In addition, when the exposure light with a wavelength of 157 nm is used as the liquid for liquid immersion lithography, a fluorine-containing medium is a likely candidate for the liquid for liquid immersion lithography from the viewpoint of the exposure light absorption. Even when such a fluorine-containing solvent is used, as in the case of the water mentioned above, it sufficiently protects the resist film during the liquid immersion lithography process so that the resist pattern with excellent properties can be obtained.

Furthermore, since the material forming a protective film of the present invention is alkali-soluble (developing solution), it is not necessary to remove the formed protective film from the resist film before a development treatment even when the development treatment is conducted after the completion of the exposure. Namely, since the protective film obtained by using the material for forming a protective film of the present invention is soluble in an alkaline (developing solution), it is not necessary to provide a protective-film removing step before the developing step after exposure, and the development treatment of the resist film with an alkaline developing solution can be conducted without removing the protective film, thereby making it possible to simultaneously conduct the removal of the protective film and the development of the resist film. Therefore, the method for forming the pattern using the material for forming a protective film according to the present invention can efficiently perform the formation of the resist film with an excellent pattern properties keeping the environmental pollution risk extremely low and reducing the number of steps.

Particularly, since the alkali-soluble polymer used as the material for forming a protective film of the present invention is soluble in various kinds of alcohol, it is possible to provide a material for forming a protective film with favorable coating properties. Moreover, since the protective film formed by using the material for forming a protective film of the present invention is insoluble to water and soluble to a developing solution, the shape of the resist pattern does not substantially change even when the protective film is used for the liquid immersion lithography process.

### PREFERRED MODE FOR CARRYING OUT THE INVENTION

In the present invention with the above-mentioned constitution, liquid immersion lithography can be conducted by using, as the liquid for liquid immersion lithography, water consisting of substantially of purified water or deionized water, or a fluorine-based inert squid. As described previously, taking into account the cost efficiency, the simple post-treatment, and the reduced environmental pollution, water is a more preferable liquid for liquid immersion lithography. When exposure light having a wavelength of 157 nm is used, it is preferable to use a fluorine-based solvent that causes less absorption of exposure light. Furthermore, the protective film formed from the material for forming a protective film of the present invention is dense, and therefore can suppress permeation of the liquid for immersion lithography through the resist film.

The resist film, which can be used in the present invention, may be any resist film obtained by using a conventional common resist composition, and is not specifically limited. This is also a primary feature of the present invention.

As described above, the essential characteristics as a protective film of the present invention are substantial water insolubility, alkali solubility, and furthermore, transparency to the exposure light, immiscibility in the resist film, superior adherence to the resist film, and excellent solubility in the developing solution. As the material for forming a protective film, the material enabling to form a protective film having these characteristics, a composition can be used which is prepared by dissolving, an alkali-soluble polymer having at least any one of constitutional units represented by the following general formulas (I) and (II) in an alcoholic solvent.

More specifically, as the constitutional unit represented by the general formula (I), a constitutional unit represented by the following general formula (III) can be preferably used.

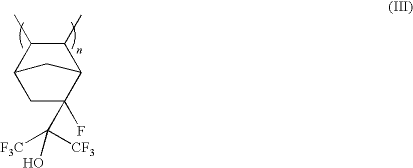

In addition, more specifically, as the constitutional unit represented by the general formula (II), the constitutional unit represented by the following general formula (IV) is preferably used.

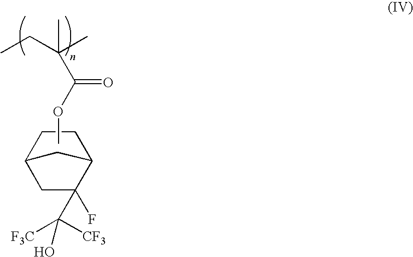

The alkali-soluble polymer used in the present invention may be a copolymer and/or a mixed polymer of the constitutional unit represented by the general formula (I) and/or the constitutional unit represented by the general formula (II) with the constitutional unit represented by the following general formula (V). Such a constitution makes it possible to improve alkali-solubility.

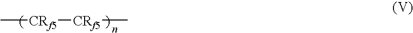

In the formula (V), R_{f5} represents a hydrogen atom, or a liner, branched, or cyclic alkyl group having 1 to 5 carbon atoms, provided that some or all of hydrogen atoms of the alkyl group may be substituted with fluorine atoms, on condition that all R_{f5}s of the alkali-soluble polymer is not hydrogen atoms at the same time, and is an integer of not less than 1, representing the number of repeating units.

Such a polymer can be synthesized by a known polymerization method. The weight average molecular weights of resins of these polymer components (by GPC, polystyrene conversion) is not particularly limited, but preferably falls within the range of 5,000 to 80,000, and more preferably 8,000 to 50,000.

As the solvent dissolving the alkali-soluble polymer, any solvent incompatible with a resist film and capable of dissolving the fluoropolymer can be used. Examples of such a solvent include an alcoholic solvent. The alcoholic solvent is an alcoholic solvent having 1 to 10 carbon atoms, and more specifically, n-butyl alcohol, isobutyl alcohol, n-pentanol, 4-methyl-2-pentanol, and 2-octanol are preferable.

As a solvent to dissolve the alkali-soluble polymer, it is also possible to use a fluorine atom-containing alcoholic solvent. Such a fluorine atom-containing alcoholic solvent is also incompatible with a resist film and capable of dissolving the alkali-soluble polymer. As the fluorine atom-containing alcoholic solvent, the one which contains more fluorine atoms than hydrogen atoms is preferable.

It is preferable that the number of carbon atoms in the fluorine atom-containing alcoholic solvent is from 4 to 12. Specifically, as such a fluorine atom-containing alcoholic solvent, C₄F₉CH₂CH₂OH and/or C₃F₇CH₂OH can be preferably used.

In addition, the material for forming a protective film of the present invention can be combined, with an acidic substance. As the acidic substance, a fluorocarbon compound is preferably used. By adding fluorocarbon compound to the material for forming a protective film of the present invention, the effect of improving the shape of the resist pattern is achieved.

Such fluorocarbon compounds shown below are not the subject to the Significant New Use Rule (SNUR) and thus are usable.

As such fluorocarbon compounds, the compounds represented by the following general formula (201),

(CₙF₂ₙ₊₁SO₂)₂NH (201)

wherein n represents an integer of 1 to 5; the following general formula (202),

CₘF₂ₘ₊₁COOH (202)

wherein m represents an integer of 10 to 15; the general formula (203); and the general formula (204) are preferable,

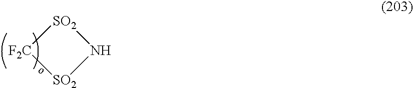

wherein o represents an integer of 2 to 3; and

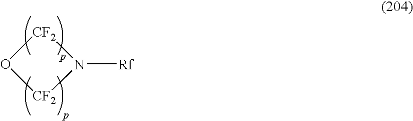

wherein p represents an integer of 2 to 3; and Rf represents an alkyl group in which some or all of hydrogen atoms are substituted with fluorine atoms, and may be substituted with a hydroxyl group, an alkoxy group, a carboxyl group, or an amino group.

Specifically, the fluorocarbon compound represented by the general formula (201) is preferably a fluorocarbon compound represented by the following chemical formula (205),

(C₄F₉SO₂)₂NH (205)

or a fluorocarbon compound represented by the following chemical formula (206),

(C₃F₇SO₂)₂NH (206).

In addition, as the fluorocarbon compound represented by the general formula (202), specifically, the fluorocarbon compound represented by the following chemical formula (207) is preferable.

C₁₀F₂₁COOH (207)

Specifically, as the fluorocarbon compound represented by the general formula (203), the fluorocarbon compound represented by the following chemical formula (208) is preferable.

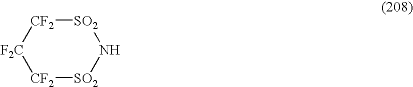

Specifically, as the fluorocarbon compound represented by the general formula (204), the fluorocarbon compound represented by the following chemical formula (209) is preferable.

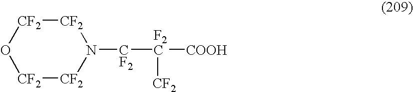

The material for forming a resist protective film of this invention may be combined with a crosslinking agent comprising a nitrogen-containing compound having an amino group and/or an imino group, which is substituted with a hydroxyalkyl group and/or an alkoxyalkyl group.

As the nitrogen-containing compound, least one derivative selected from a melamine derivative, a guanamine derivative, a glycoluril derivative, a succinylamide derivative, and a urea derivative is preferably used.

Specifically, these nitrogen-containing compounds can be obtained, for example, by methylolating the melamine-based compound, urea-based compound, guanamine-based compound, acetoguanamine-based compound, benzoguanamine-based compound, glycoluril-based compound, succinylamide-based compound or ethyleneurea-based compound with formalin in boiling water, and optionally further alkoxylating the reaction product with a lower alcohol such as methanol, ethanol, n-propanol, isopropanol, n-butanol, and isobutanol.

As such a crosslinking agent, tetrabutoxymethylated glycoluril is more preferably used.

Furthermore, as the crosslinking agent, condensation reaction product of a hydrocarbon compound substituted with at least one of a hydroxyl group and/or a alkyloxy group and a monohydroxymonocarboxylic acid compound can also be preferably used.

The monohydroxymonocarboxylic acid in which a hydroxyl group and a carboxyl group are bonded with the same carbon atom or the two adjacent carbon atoms respectively is preferable.

A method for forming a photoresist pattern by liquid immersion lithography using the protective film of the present invention is described below.

First, a common resist composition is coated onto a substrate such as silicone wafer with a spinner or the like and then prebaked (FAB treatment). An organic or inorganic antireflective film can be provided between the substrate and a coating layer of the resist composition, to form a two-layered laminate.

The above processes can be conducted by a known method. It is preferable that the operation conditions are appropriately set according to the composition and characteristics of a resist composition used.

Next, to the surface of the resist film (monolayered or multilayered) which has been cured as described above, the material for forming a protective film of the present invention, for example “a composition prepared by dissolving an alkali-soluble polymer having each of the constituent units represented by the chemical formulas (I) and (II) in isobutyl alcohol” is evenly applied and cured, thereby forming a resist protective film.

On the substrate on which the resist film covered with the protective film has been formed, the liquid for liquid immersion lithography (a liquid having a refractive index that is larger than that of air and smaller than that of the resist film (purified water, deionized water, or fluorine-based solvent in the case specialized in the present invention) is placed.

The resist film on the substrate in this state is selectively exposed through a desired mask pattern. Accordingly, exposure light penetrates into the liquid for liquid immersion lithography and the protective film, reaching the resist film at this time.

At this time, the protective film completely shuts the resist film off from the liquid for liquid immersion lithography such as purified water, and thus it effectively controls the deterioration such as expansion caused by the permeation of the liquid for liquid immersion lithography and the deterioration of optical properties such as the refractive index of the liquid for liquid immersion lithography caused by the elution of components into the liquid for liquid immersion lithography such as purified water, deionized water, or a fluorine-based solvent.

The wavelength of light used the exposure is not specifically limited, and the exposure can be conducted by using radiation such as an ArF excimer laser, KrF excimer laser, F₂ excimer laser, EUV (extreme ultraviolet ray), VUV (vacuum ultraviolet ray), electron beam, X-ray, and soft X-ray. The kind of radiation is mainly decided according to characteristics of a resist film.

As described above, in the method for forming a resist pattern of the present invention, a liquid for liquid immersion lithography having a refractive index larger than that of air and smaller than that of the resist film employed is disposed onto the resist film via a protective film upon exposure. Examples of such a liquid include water (purified water, deionized water), or a fluorine-based inert liquid. A specific example of the fluorine-based inert liquid includes a liquid containing a fluorine-based compound such as C₃HCl₂F₅, C₄F₉OCH, C₄F₉OC₂H₅ and C₅H₃F₇ as a main component. Among these liquids, in view of cost, safety, environmental problems, and general versality, the use of water (purified water or deionized water) is preferable. When using exposure light having a wavelength of 157 nit, a fluorine-based solvent is preferably used in view of less absorption of exposure light.

The refractive index of the refractive index liquid used is not particularly limited as long as it is within a range “larger than the refractive index of air and smaller than that of a resist composition to be used”.

After the exposing step in the liquid immersion state is completed, the liquid for liquid immersion lithography is removed from the substrate.

Next, the resist film is subjected to PEE (post exposure baking), followed by a development treatment using an alkaline developing solution including an aqueous alkaline solution. Since the developing solution used in this development process is alkaline, the protective film is dissolved away simultaneously with the soluble portion of the resist film. The development treatment may be followed by postbaking. Subsequently, the resist film is rinsed by using deionized water or the like the water rinsing process, for example, water is dripped or sprayed over the surface of the substrate while rotating, thereby washing away the protective film component and the resist composition dissolved by the developing solution, and the developing solution on the substrate. Then, a resist pattern in which a resist film is patterned in a shape corresponding to a mask pattern is obtained by drying. As described above, in the present invention, removal of the protective film and the development of the resist film are simultaneously achieved by the development treatment. Because the protective film formed by the material for forming a protective film of the present invention has improved water-shedding properties, the liquid for liquid immersion lithography can be easily separated after the exposure is completed, and the adhesive amount (i.e. leakage) of the liquid for liquid immersion lithography is reduced.

By forming resist patterns in this way, resist patterns having fine line widths, particularly line-and-space patterns having a small pitch can be produced with excellent resolution. Here, the term “pitch” in the line-and-space patterns refers to a total distance of a resist pattern width and a space width in the line width direction of the patterns.

### EXAMPLES

Hereinafter, examples of the present invention will be described. However, these examples are only provided for appropriately illustrating the present invention and do not intend to restrict the present invention at all.

### Example 1

In this example, a protective film was formed on the substrate by using the material for forming a protective film according to the present invention, and the water resistance and solubility the alkaline developing solution of this protective firm were evaluated. A material for forming a protective film was prepared by the following. A copolymer represented by the following general formula (VI) (molecular weight was 4,400, x:y=50:50 (mol)) was used as a base polymer, 2-methyl-1-propanol was used as a solvent, and polymer density was adjusted to 3% by mass.

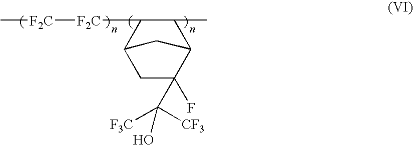

First, solubility of the base polymer to the solvent was evaluated. The base polymer was added into two kinds of solvents (2-methyl-1-propanol and 4-methyl-2-pentanol), and the solubility was examined. It was verified that the base polymer was soluble in both of the two kinds of alcoholic solvents.

Furthermore, the material for forming a protective film was coated onto a semiconductor substrate under coating conditions of 2000 rpm by using a spin coater. After the coating, a protective film for evaluation was obtained by being cured through a heat treatment at 90° C. for 60 seconds. The protective film had a thickness of 70.0 nm.

The protective film was evaluated with respect to three items: (i) visual observation of the surface state; (ii) measurement of the amount of thickness loss after rinsing with purified water for 120 seconds to simulate solubility in the liquid for liquid immersion lithography (purified water); and (iii) measurement of the dissolution rate (in terms of film thickness: nm/second) of the protective film in an alkaline developing solution (2.38% aqueous solution of tetramethylammonium hydroxide). As a result, the surface state was visually observed to be excellent, and no change in film thickness before and after purified water rinse was found, and the dissolution rate of the protective film in the developing solution was not less than 100 nm/sec by measuring with Resist Dissolution Analyzer(RDA: manufactured by Litho Tech Japan Co., Ltd.). Therefore, it was verified that the protective film had sufficient properties.

### Example 2

An organic composition for antireflective film, “ARC29” (product name, manufactured by Brewer Science Inc.) was coated on a silicone wafer by using a spinner and then dried by baking on a hot plate at 205° C. for 60 seconds to form an organic antireflective film having a thickness of 77 nm. Subsequently, a positive type resist “TArF-P6111ME” (manufactured by Tokyo Ohka Kogyo Co., Ltd.) was applied on this antireflective film by a spinner, pre-baked on a hot plate at 130° C. for 90 seconds, and then dried. Consequently, a resist film having a film thickness of 225 nm was formed on the antireflective film.

The copolymer represented by the chemical formula (VI) (the molecular weight was 4,400, x:y=50:50 (mol %)) was dissolved in 2-methyl-1-propylalcohol, the resulting mixture in which the resin concentration was 3.0% by mass was spin-coated on the resist film, and then heated at 90° C. for 60 seconds to form a protective film having a thickness of 70 nm.

Next, patterning light was irradiated (exposed) through mask patterns by an exposure device NSR-S302A (manufactured by Nikon Corp., NA (numerical aperture)=0.60, σ=⅔ orbicular zone) using ArF Excimer laser (wavelength=193 nm). After the exposing treatment, purified water was continuously dripped onto the resist film at 23° C. for minutes while rotating the substrate, thereby establishing a pseudo-immersion environment.

After the process of dropping purified water, a PEB treatment was conducted at 130° C. for 90 seconds, and the resist film was developed with the alkaline developing solution at 23° C. for 60 seconds, remaining the protective film on the resist film. As the alkaline developing solution, 2.38% by mass aqueous solution of tetramethylammonium hydroxide (TMAH) was used. The protective film was completely removed by this development process, and the development of the resist film was also satisfactorily achieved.

The resulting resist pattern with a 1:1 line-and-space of 130 nm was observed with a scanning electron microscope (SEM). The pattern profile was excellent and no fluctuation or the like was observed at all.

### Example 3

Subsequently, a positive type resist “TArF-P6111ME” (manufactured by Tokyo Ohka Kogyo Co., Ltd) was applied on the silicon wafer with a spinner and dried by pre-baking on a hot plate at 130° C. for 90 seconds, thereby forming a resist film with a film thickness of 150 nm.

The material for forming a protective film similar to that of Example 1 was spin-coated on the resist film, followed by heating, at 90° C. for 60 seconds to form a protective film having a film thickness of 70.0 nm.

Using a testing device LEIES 193-1 (manufactured by Nikon Corporation) for liquid immersion lithography, a two-beam interference test was Conducted regarding liquid immersion lithography. Subsequently, a PEE treatment was conducted at 115° C. for 90 seconds, and a development treatment was conducted at 23° C. for 60 seconds by using 2,38% by mass aqueous TMAH solution. The protective film was completely removed this development process, and the development of the photoresist film was also satisfactorily achieved.

The resulting resist pattern with a 1:1 line-and-space of 65 nm was observed with a scanning electron microscope (SEM), and then it was found that a line-and-space pattern with an excellent shape was formed.

### Comparative Example 1

By using the positive photoresist similar to that of Example 2, a resist pattern (1:1 line-and-space of 130 nm) was formed in the similar manner to Example 2 except that no protective film, and then observed with a scanning electron microscope (SEM). The fluctuation, expansion or the like of the pattern was not observed.

### INDUSTRIAL APPLICABILITY

As described above, according to the present invention, it is possible to obtain a highly accurate resist pattern having high sensitivity and superior resist pattern profile, excellent focal depth, exposure latitude, and post exposure delay stability, even if a resist film is formed by using any conventional resist composition, or the type of liquid for liquid immersion lithography, particularly water or a fluorine-based medium is used in a liquid immersion lithography process. In addition, the quality of the film is dense, the deterioration of the resist film and the liquid for liquid immersion lithography employed can be prevented simultaneously during id immersion lithography using various liquids for liquid immersion lithography including water, and resistance to post exposure delay of the resist film can be improved without increasing the number of processes. Consequently, by using the material for forming a protective film of the present invention, a resist pattern can be effectively formed by using a liquid immersion lithography process.

1. A material for forming a protective film laminated on a photoresist film on a substrate, the material being prepared by dissolving an alkali-soluble polymer having at least any one of constitutional units represented by the following general formulas (I) and (II) in an alcoholic solvent, 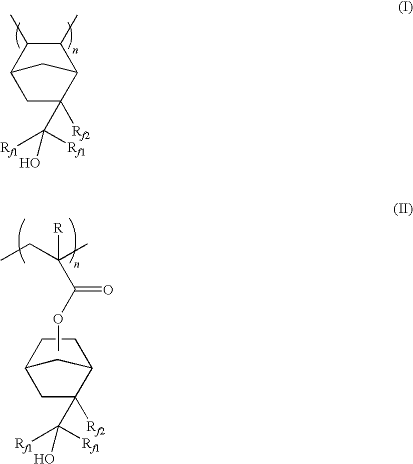
wherein R_{f1} represents a liner, branched, or cyclic alkyl group having 1 to 5 carbon atoms, provided that some or all of hydrogen atoms of the alkyl group may be substituted with fluorine atoms;
R_{f2} represents a hydrogen atom, a fluorine atom, or a liner, branched, or cyclic alkyl group having 1 to 5 carbon atoms, provided that some or all of hydrogen atoms of the alkyl group may be substituted with fluorine atoms;
at least any one of R_{f1} and R_{f2} has a fluorine substituent;
R represents a hydrogen atom or a methyl group; and
n is an integer of not less than I, representing the number of repeating units.

2. The material for forming a protective film according to claim 1, wherein the material is used in a liquid immersion lithography process.

3. The material for forming a protective film according to claim 1, wherein the constitutional unit represented by the general formula (I) is a constitutional unit represented by the following general formula (III).

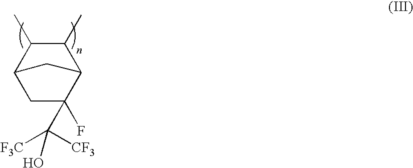

4. The material for forming a protective film according to claim 1, wherein the constitutional unit represented by the general formula (II) is a constitutional unit represented by the following general formula (IV).

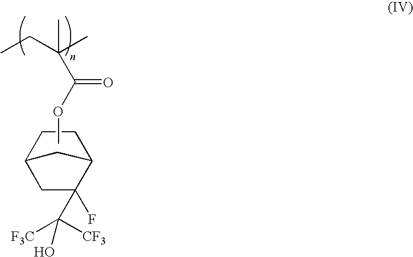

5. The material for forming a protective film according to claim 1, wherein the alkali-soluble polymer is a copolymer and/or a mixed polymer of the constitutional unit represented by the general formula (I) and/or the constitutional unit represented by the general formula (II) with a constitutional unit represented by the following general formula (V), 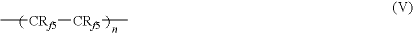
wherein, R_{f5} represents a hydrogen atom, a fluorine atom, or a liner, branched, or cyclic alkyl group having 1 to 5 carbon atoms, provided that some or all of hydrogen atoms of the alkyl group may be substituted with fluorine atoms, on condition that all R_{f5}s of the alkali-soluble polymer are not become hydrogen atoms at the same time; and
n is an integer of not less than 1, representing the number of repeating units.

6. The material for forming a protective film according to claim 1, wherein the alcoholic solvent has 1 to 10 carbon atoms.

7. The material for forming a protective film according to claim 6, wherein the alcoholic solvent is at least one selected from n-butyl alcohol, isobutyl alcohol, n-pentanol, 4-methyl-2-pentanol, and 2-octanol.

8. The material for forming a protective film according to claim 1, wherein the alcoholic solvent includes at least a fluorine atom-containing alcoholic solvent.

9. The material for forming a protective film according to claim 8, wherein the fluorine atom-containing alcoholic solvent is C₄F₉CH₂CH₂OH and/or C₃F₇CH₂OH.

10. The material for forming a protective film according to claim 1, further comprising an acidic substance.

11. The material for forming a protective film according to claim 10, wherein the acidic substance is a fluorocarbon compound.

12. The material for forming a protective film according to claim 1, further comprising a crosslinking agent.

13. The material for forming a protective film according to claim 12, wherein the crosslinking agent is a nitrogen-containing compound having an amino group and/or an imino group, in which at least two hydrogen atoms are substituted with a hydroxyalkyl group and/or an alkoxyalkyl group.

14. A method for forming a photoresist pattern by using a liquid immersion lithography process,
the method comprising:
a photoresist-forming step of forming a photoresist film on a substrate;
a protective-film forming step of forming a protective film on the photoresist film by using the material for forming a protective film according to claim 1;
an exposing step of selectively exposing the photoresist film through a liquid for liquid immersion lithography and the protective film after the liquid for the liquid immersion lithography is placed at least on the protective film of the substrate; and
a developing step of developing the protective film and the photoresist film by using an alkaline developing solution after a heat treatment is conducted to the photoresist film if necessary, thereby removing the protective film and obtaining a photoresist pattern, at the same time.
